(19) United States
(12) Patent Application Publication
(10) Pub. No.: US 2009/0166805 A1
(43) Pub. Date: Jul. 2, 2009

(54) Metal Insulator Metal Capacitor and Method of Manufacturing the Same

(76) Inventor: Jong Yong Yun, Gangnam-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/247,261

(22) Filed: Oct. 8, 2008

(30) Foreign Application Priority Data
Dec. 26, 2007 (KR) 10-2007-0137242

(51) Int. Cl. H01L 29/92; H01L 21/02

(52) U.S. Cl. 257/532; 438/396; 257/E29.343; 257/E21.011

(57) ABSTRACT

Disclosed are a metal insulator metal (MIM) capacitor and a method of manufacturing a MIM capacitor. The MIM capacitor includes a lower metal interconnection layer, a dielectric layer pattern formed on the lower metal interconnection layer, and a third metal layer pattern formed on the dielectric layer pattern. The dielectric layer pattern has a concave surface that can be formed by performing an isotropic etching process. Accordingly, the third metal layer pattern fills the concave surface, resulting in a larger surface contact area between the dielectric material and the metal material of the MIM capacitor.

### CROSS REFERENCE TO RELATED APPLICATION

The present application claims the benefit under 35 U.S.C. §119 of Korean Patent Application No. 10-2007-0137242, filed Dec. 26, 2007, which is hereby incorporated by reference in its entirety.

### BACKGROUND

Recently, as semiconductor process technology has been rapidly developed, the performance of a capacitor has been improved for use in applications such as a digital/analog (D/A) converter, an analog/digital (A/D) converter, a merged memory lock device, and so on.

Referring to FIG. 1, a related art metal insulator metal (MIM) capacitor can include a lower metal interconnection layer 10, a dielectric pattern 20, and an upper electrode pattern 30

Since the MIM capacitor has a stacked structure covering an area of a substrate, it is limited to realize a small-size MIM capacitor because of the trend to integrate a micro-sized semiconductor device covering smaller areas of the substrate.

In particular, because the cross-sectional area of both the dielectric pattern 20 and the upper electrode pattern 30 are limited in size, it is difficult to improve the capacitance of the MIM capacitor.

### BRIEF SUMMARY

Embodiments of the present invention provide a MIM capacitor having increased capacitance and a method of manufacturing the same, which is suitable for a small-sized space, by enlarging a cross-sectional area between a dielectric substance and a metal substance.

According to an embodiment, a metal insulator metal (MIM) capacitor can include a lower metal interconnection layer, a dielectric layer pattern formed on the lower metal interconnection layer, and a third metal layer pattern formed on the dielectric layer pattern. The dielectric layer pattern has a recessed portion on its top surface and the third metal layer pattern fills the recessed portion.

A method of manufacturing a MIM capacitor according to an embodiment includes forming a dielectric layer on a lower metal interconnection layer, forming a recessed portion in a surface of the dielectric layer, forming a third metal layer on the dielectric layer filling the recessed portion, and forming a dielectric layer pattern and a third metal layer pattern by patterning the dielectric layer and the third metal layer.

### BRIEF DESCRIPTION OF THE DRAWINGS

FIG. 1 is a cross-sectional view of a MIM capacitor according to the related art.

FIGS. 2 to 7 are cross-sectional views for illustrating a method of manufacturing a MIM capacitor according to an embodiment of the present invention.

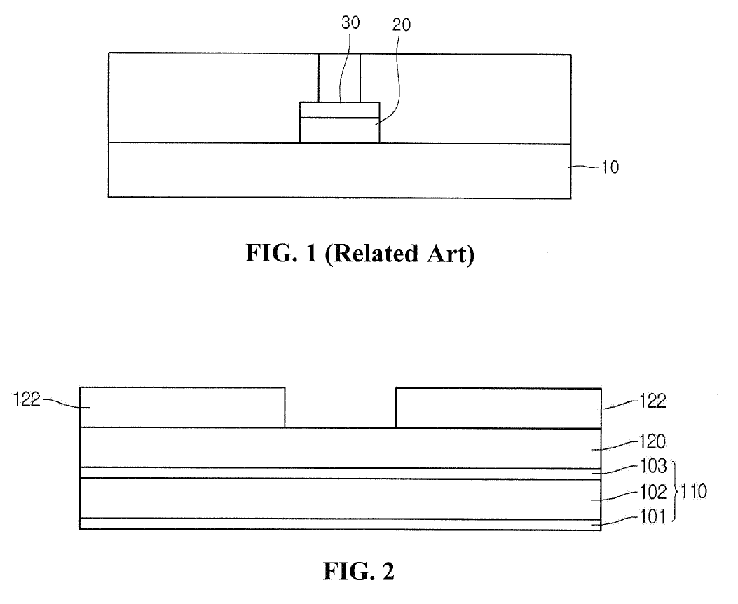

### DETAILED DESCRIPTION

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

Hereinafter, a MIM capacitor and a method of manufacturing the same according to an embodiment will be described in detail with reference to accompanying drawings.

Referring to FIG. 2, a lower metal interconnection layer 110 including a first metal layer 101, a first metal interconnection layer 102, and a second metal layer 103 can be formed on a semiconductor substrate (not shown).

The first and second metal layers 101 and 103 can include TiN, and the first metal interconnection layer 102 can include aluminum.

The first and second metal layers 101 and 103 can be included to improve the electric contact property of the first metal interconnection layer 102.

A dielectric layer 120 can be formed on the lower metal interconnection layer 110. In one embodiment, the dielectric layer 120 can include SiON.

After forming the dielectric layer 120, a first photoresist layer can be coated on the substrate and an exposure and development process can be performed with respect to the first photoresist layer to form a first photoresist pattern 122.

A first etching process can be performed to etch a portion of the surface of the dielectric layer 120 using the first photoresist pattern 122 as an etching mask.

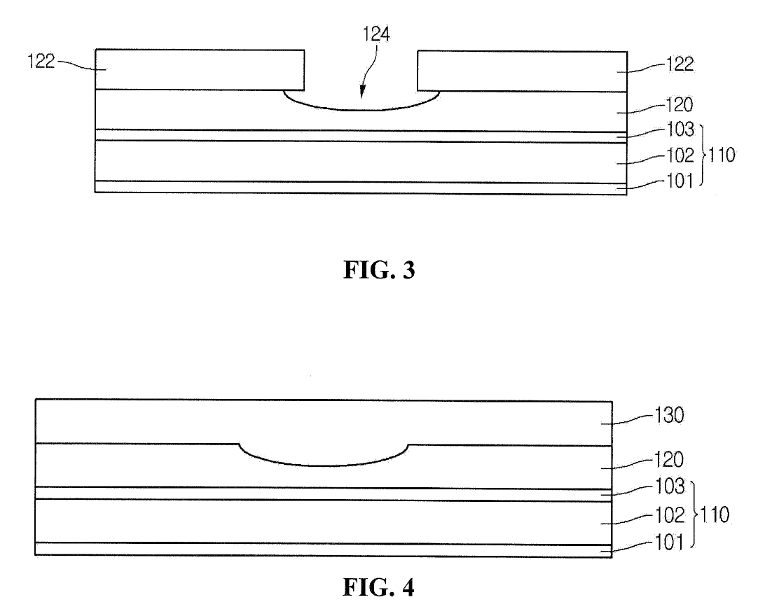

According to an embodiment, the first etching process can be performed using isotropic etching equipment to etch the dielectric layer 120. Referring to FIG. 3, the dielectric layer 120 under the edges of the first photoresist pattern 122 is also partially etched.

As the first etching process has been performed, a recessed portion 124 having a concave-up shape can be formed in a part of an upper portion of the dielectric layer 120.

Then, the first photoresist pattern 122 can be removed.

Referring to FIG. 4, a third metal layer 130 can be deposited on the dielectric layer 120, filling the recessed portion 124. In one embodiment, the third metal layer 130 can be planarized after filling the recessed portion 124.

The third metal layer 130 can include a metal material such as TiN.

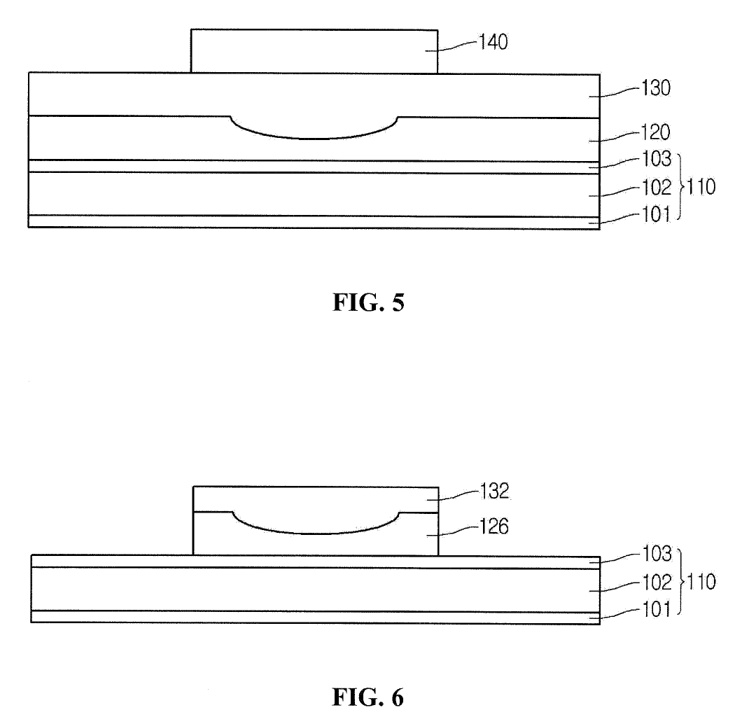

Referring to FIG. 5, a second photoresist layer can be coated on the third metal layer 130, and an exposure and development process can be performed with respect to the second photoresist layer to form a second photoresist pattern 140.

When viewed in a plan view, the second photoresist pattern 140 can cover the recessed portion 124 and a portion of the third metal layer 130 provided at both sides of the recessed portion 124.

As shown in FIG. 6, a second etching process can be per formed using the second photoresist pattern 140 as an etching mask to form a dielectric layer pattern 126, including the recessed portion 124, and a third metal layer pattern 132.

The dielectric layer pattern 126 serves as a dielectric substance of a capacitor, and the third metal layer pattern 132 serves as an upper electrode of the capacitor.

In addition, a portion of the second metal layer 103 making contact with the dielectric layer pattern 126 can serve as a lower metal electrode of the capacitor.

After performing the second etching process, the second photoresist pattern 140 can be removed.

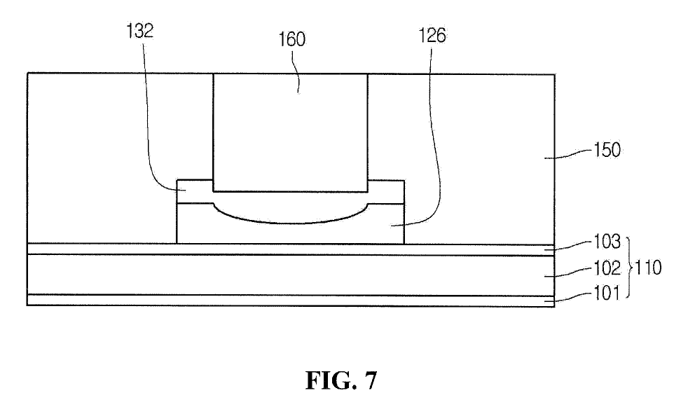

Referring to FIG. 7, an insulating layer 150 can be deposited to cover both the dielectric layer pattern 126 and the third metal layer pattern 132, and a polishing process such as a chemical mechanical polishing (CMP) process can be performed with respect to the resultant structure to planarize the surface of the insulating layer 150.

In an embodiment, the insulating layer 150 can include an oxide-based material.

After planarizing the surface of the insulating layer 150, a third photoresist layer can be coated on the insulating layer 150 and an exposure and development process can be performed with respect to the resultant structure to form a third photoresist pattern (not shown).

The third photoresist pattern provides an opening having a size smaller than that of the third metal layer pattern 132.

According to one embodiment, the opening of the third photoresist pattern has the same size as that of the recessed portion 124.

Then, a third etching process can be performed using the third photoresist pattern as an etching mask.

Through the third etching process, a recessed portion is formed with a height from the top surface of the insulating layer 150 to the third metal layer pattern 132.

In a further embodiment, to provide an improved electric connection, the recessed portion can be formed extending into a part of an upper portion of the third metal layer pattern 132.

After forming the recessed portion, the third photoresist can be removed.

Then, a metal material can be coated on the resultant structure to fill the recessed portion, and a planarization process can be performed to form an upper metal interconnection layer 160 in the recessed portion.

The metal material filling the recessed portion can include tungsten (W).

The contact area between the third metal layer pattern 132 and the dielectric layer pattern 126 can be enlarged through the structure of the recessed portion 124 provided on the top surface of the dielectric layer pattern 126.

The numerical value of capacitance is proportional to the contact area between a metal layer and a dielectric layer and the dielectric constant of the dielectric layer. The numerical value of the capacitance is inversely proportional to the thickness of the dielectric layer. Accordingly, the capacitance of the MIM capacitor formed according to embodiments can be improved.

In addition, the depth of the recessed portion 124 formed on the dielectric layer pattern 126 can be adjusted according to the mounting area of the dielectric layer pattern 126 and the third metal layer pattern 132. Accordingly, the capacitance of the MIM capacitor formed according to embodiments can be improved.

The profile of the recessed portion 124 can be adjusted according to an amount of an injected gas, an etching energy, and an etching temperature in the first etching process (i.e., the isotropic etching process).

In the MIM capacitor and the method of manufacturing the same according to embodiments, a recessed portion is formed in a surface of a dielectric pattern, so that the cross-sectional area between a dielectric substance and a metal substance can be enlarged. Accordingly, the capacitance of the capacitor can be increased. In addition, the mounting area for the capacitor can minimized, so that a semiconductor device can be easily integrated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A metal insulator metal (MIM) capacitor comprising:
a lower metal interconnection layer;
a dielectric layer pattern on the lower metal interconnection layer, wherein a top surface of the dielectric layer pattern has a recessed portion formed therein; and
a third metal layer pattern on the dielectric layer pattern and filling the recessed portion.

2. The MIM capacitor of claim 1, further comprising:
an insulating layer on the third metal layer pattern; and
an upper metal interconnection layer making contact with the third metal layer pattern through the insulating layer.

3. The MIM capacitor of claim 2, wherein the insulating layer comprises an oxide-based material and wherein the upper metal interconnection layer comprises tungsten.

4. The MIM capacitor of claim 1, wherein the recessed portion has a concave-up shape.

5. The MIM capacitor of claim 1, wherein the lower metal interconnection layer comprises:
a first metal layer;
a first metal interconnection layer on the first metal layer; and
a second metal layer on the first metal interconnection layer.

6. The MIM capacitor of claim 5, wherein the first metal layer and the second metal layer comprise TiN, and wherein the first metal interconnection layer comprises aluminum.

7. The MIM capacitor of claim 1, wherein the third metal layer pattern comprises TiN.

8. The MIM capacitor of claim 1, wherein the dielectric layer pattern comprises SiON.

9. A method of manufacturing a MIM capacitor, comprising:
forming a dielectric layer on a lower metal interconnection layer;
forming a recessed portion in a surface of the dielectric layer;
forming a third metal layer on the dielectric layer and filling the recessed portion; and
forming a dielectric layer pattern and a third metal layer pattern by patterning the dielectric layer and the third metal layer.

10. The method of claim 9, further comprising:
forming an insulating layer on the lower metal interconnection layer to cover the dielectric layer pattern and the third metal layer pattern; and
forming an upper metal interconnection layer making contact with the third metal layer pattern through the insulating layer.

11. The method of claim 10, wherein the insulating layer comprises an oxide-based material, and wherein the upper metal interconnection layer comprises tungsten.

12. The method of claim 10, wherein the upper metal interconnection has a same width as the recessed portion.

13. The method of claim 9, wherein the lower metal interconnection layer comprises:
a first metal layer on a substrate;
a first metal interconnection layer on the first metal layer; and
a second metal layer on the first metal interconnection layer.

14. The method of claim 13, wherein the first metal layer and the second metal layer comprise TiN, and wherein the first metal interconnection layer comprises aluminum.

15. The method of claim 9, wherein the dielectric layer comprises SiON.

16. The method of claim 9, wherein, forming the recessed portion in the surface of the dielectric layer comprises performing an etching process employing isotropic etching equipment.

17. The method of claim 9, wherein the recessed portion is formed to have a concave-up shape.

18. The method of claim 9, wherein the third metal layer comprises TiN.
